(19) United States
(12) Patent Application Publication
(10) Pub. No.: US 2016/0163928 A1
(43) Pub. Date: Jun. 9, 2016

(54) NITRIDE SEMICONDUCTOR LIGHT EMITTING ELEMENT AND METHOD FOR MANUFACTURING THE SAME

(71) Applicant: USHIO DENKI KABUSHIKI KAISHA, Tokyo (JP)

(72) Inventors: Massashi TSUKIHARA, Himeji-shi (JP); Kohei MIYOSHI, Himeji-shi (JP)

(73) Assignee: USHIO DENKI KABUSHIKI KAISHA, Tokyo (JP)

(21) Appl. No.: 14/906,704

(22) PCT Filed: Jun. 16, 2014
(86) PCT No.: PCT/JP2014/065906

§ 371 Date: Jan. 21, 2016

(30) Foreign Application Priority Data
Jul. 23, 2013 (JP) 2013-152571

(51) Int. Cl. H01L 33/32; H01L 33/00

(52) U.S. Cl. CPC H01L 33/325; H01L 33/0075

(57) ABSTRACT

To realize a nitride semiconductor light-emitting element having excellent lifespan characteristics in addition to improved light emission efficiency compared with conventional elements. A nitride semiconductor light-emitting element having a light-emitting layer obtained by alternately stacking a well layer comprising a nitride semiconductor and a barrier layer comprising a nitride semiconductor between an n-type nitride semiconductor layer and a p-type nitride semiconductor layer, wherein a final barrier layer, which is the barrier layer formed at a position in contact with the p-type nitride semiconductor layer, contains n-type impurities, and the concentration of n-type impurities at the interface with the p-type nitride semiconductor layer is 4×10¹⁷/cm³ or less.

### TECHNICAL FIELD

The present invention relates to a nitride semiconductor light-emitting element having a light-emitting layer obtained by alternately stacking at least one well layer including a nitride semiconductor and at least one barrier layer including a nitride semiconductor between an n-type nitride semiconductor layer and a p-type nitride semiconductor layer, as well as to a method for manufacturing the same.

### BACKGROUND ART

Today, a nitride semiconductor is used and developed for use in various light-emitting elements such as an LED (light-emitting diode) and an LD (laser diode) (for example, see Patent Documents 1 and 2). Recently, the nitride semiconductor is being developed also for use in an element that emits ultraviolet light or light having a shorter wavelength than that.

Generally, in a nitride semiconductor light-emitting element, a structure is adopted in which a light-emitting layer obtained by alternately stacking at least one well layer including a nitride semiconductor and at least one barrier layer including a nitride semiconductor is formed between an n-type nitride semiconductor layer and a p-type nitride semiconductor layer. The following Patent Documents 1 and 2 each describe characteristic features related to the structure of the light-emitting layer.

Patent Document 1 discloses a construction in which a final barrier layer (also referred to as “last barrier layer”), which is a barrier layer located at the outermost side of the light-emitting layer and is adjacent to the p-type nitride semiconductor layer, is not allowed to contain n-type impurities while the other barrier layer(s) are allowed to contain n-type impurities.

Patent Document 1 gives the following description. “Conventionally, because the final barrier layer is doped with n-type impurities, the final barrier layer comes to contain n-type impurities and p-type impurities due to diffusion of the p-type impurities from the p-type nitride semiconductor layer formed adjacent to the final barrier layer, thereby decreasing the lifetime of the carriers. However, because of adopting the construction of Patent Document 1, it is possible to prevent a situation in which the n-type impurities and the p-type impurities are present together in the final barrier layer, thereby improving the element lifespan and reverse withstand voltage characteristics.”

Patent Document 2 discloses a construction in which the well layer is let undoped while the barrier layer is doped with n-type impurities, and discloses a construction in which at least the last well layer is let undoped, and the last barrier layer, that is, the final barrier layer, is doped with n-type impurities. Patent Document 2 gives a description that, according to such a construction, a laser element having a low threshold current density and a long lifespan can be realized.

Patent Document 2 gives the following description. “When the barrier layer is doped with n-type impurities, the carrier concentration of the well layer increases, so that the threshold decreases. Conversely, when the barrier layer is intentionally doped with p-type impurities, the threshold is unlikely to decrease. For this reason, it is preferable that the barrier layer is doped only with n-type impurities. Further, when the barrier layer is doped with n-type impurities, the carrier concentration of the well layer increases, so that the spatial separation of electrons and positive holes due to the quantum Stark effect of the piezo effect due to strain is screened, whereby the threshold decreases. Conversely, when the well layer is doped with impurities, the crystallinity is deteriorated, so that the scattering of carriers increases, whereby the threshold tends to increase. In a multiquantum well structure, it is preferable that the side adjacent to the p-side nitride semiconductor layer ends with a barrier layer.”

Further, Patent Document 2 also gives the following description. “In a multiquantum well structure, the threshold tends to decrease when the structure ends with a barrier layer rather than when the structure ends with a well layer. The threshold further decreases when the last well layer is let undoped and the barrier layer is doped with n-type impurities. The reason therefor is not definite. However, it seems that, in the case of a nitride semiconductor, the effective mass of the holes is large, and the holes injected into the active layer are locally present on the p-layer side, so that only the well layers on the p-layer side emit light. Therefore, the well layers close to the n-layer side do not contribute much to light emission, and the ratio of contribution to light emission is higher in the well layers close to the p-layer side. For this reason, it is surmised that the efficiency is most improved when the well layer that is the closest to the p-layer side is let undoped and the barrier layer is doped with n-type impurities.”

### PRIOR ART DOCUMENTS

### Patent Documents

Patent Document 1: Japanese Patent No. 3498697

Patent Document 2: JP-A-11-298090

### SUMMARY OF THE INVENTION

### Problems to be Solved by the Invention

Patent Documents 1 and 2 each disclose contents characterized in the construction of the light-emitting layer, aiming at an improvement in the element lifespan; however, the contents of the two documents are incompatible with each other. In other words, while Patent Document 1 gives a description that the final barrier layer is not allowed to contain n-type impurities, Patent Document 2 gives a description that the final well layer is let undoped, and the final barrier layer is allowed to contain n-type impurities.

However, according to eager researches made by the present inventors, it has been found out that, when the final barrier layer is formed under predetermined conditions, an element exhibiting excellent lifespan characteristics can be realized while realizing a further higher light emission efficiency than the nitride semiconductor light-emitting elements disclosed in Patent Documents 1 and 2.

In other words, an object of the present invention is to realize a nitride semiconductor light-emitting element having excellent lifespan characteristics while improving light emission efficiency as compared with conventional elements.

### Means for Solving the Problems

A nitride semiconductor light-emitting element according to the present invention has:

an n-type nitride semiconductor layer;

a p-type nitride semiconductor layer; and

a light-emitting layer formed between the n-type nitride semiconductor layer and the p-type nitride semiconductor layer,

the light-emitting layer being obtained by alternately stacking at least one well layer including a nitride semiconductor and at least one barrier layer including a nitride semiconductor,

wherein a final barrier layer among the barrier layer(s), which is a barrier layer formed at a position in contact with the p-type nitride semiconductor layer, contains n-type impurities, and the concentration of the n-type impurities at an interface with the p-type nitride semiconductor layer is 4×10¹⁷/cm³ or less.

It seems that, in the case of the construction in which the final barrier layer adjacent to the p-type nitride semiconductor layer is let undoped, the layer does not contain n-type impurities, so that the piezo relaxation does not occur, thereby inviting decrease in the light emission efficiency. On the other hand, it seems that, when the final barrier layer is too much doped with n-type impurities, the n-type impurities diffused from the final barrier layer migrate in a large amount into the p-type nitride semiconductor layer, thereby inviting decrease in the characteristics.

As will be described later with reference to the examples in the section of “MODE FOR CARRYING OUT THE INVENTION,” it has been found out by eager researches of the present inventors that the light emission efficiency can be improved, as compared with the construction in which the final barrier layer is let undoped, by allowing at least the final barrier layer among the barrier layer(s) to contain n-type impurities and, with regard to the n-type impurity concentration thereof, setting the n-type impurity concentration at the interface with the p-type nitride semiconductor layer to be 4×10¹⁷/cm³ or less.

The n-type impurity concentration at the interface between the final barrier layer and the p-type nitride semiconductor layer can be confirmed by using SIMS (Secondary Ion Mass Spectrometry) or the like. In measuring the impurity concentration using SIMS or the like, composition evaluation is carried out while etching the nitride semiconductor light-emitting element at a predetermined pitch in the depth direction from the surface of the element. In this case, the obtained values of the composition ratio assume discontinuous (discrete) values that accord to the pitch of etching. Therefore, there is a possibility such that, depending on the pitch, the composition of the measurement point at which the measurement has been carried out in the pitch immediately before the relevant pitch is the composition of the measurement point that is in the p-type nitride semiconductor layer and is the closest to the final barrier layer, and the composition ratio of the measurement point at which the measurement has been carried out in the pitch immediately after the relevant pitch is the composition of the measurement point that is in the final barrier layer and is the closest to the p-type nitride semiconductor layer. In this case, it is not possible to measure the n-type impurity concentration at the interface between the final barrier layer and the p-type nitride semiconductor layer in the strict sense of the word.

Therefore, in the present description, the interface between the final barrier layer and the p-type nitride semiconductor layer is defined to be a site where the composition difference between the final barrier layer and the p-type nitride semiconductor layer is ½. At this time, the position of the above interface can be determined by linearly interpolating the values of the composition ratio at the measurement points that are discretely measured by the above method and deducing the site at which the composition difference is ½. Similarly, with respect to the value of the n-type impurity concentration, the value at the position of the interface that has been determined by the above method can be determined by linearly interpolating the values deduced at the measurement points. The light emission efficiency and the lifespan characteristics are improved, as compared with conventional light-emitting elements, when the n-type impurity concentration at the interface thus determined is 4×10¹⁷/cm³ or less. Since the final barrier layer contains n-type impurities, the n-type impurity concentration at the interface is more than or equal to a predetermined amount, and the final barrier layer is not undoped.

In determining the n-type impurity concentration at the interface by the above method, the measurement pitch is preferably 5 nm or less, more preferably 2 nm or less, in view of improving the precision thereof.

As compared with electrons, positive holes have a higher effective mass and lower mobility. For this reason, it seems that, even in a light-emitting layer having a plurality of well layers, the well layer(s) on the side close to the p-type nitride semiconductor layer constitute sites that particularly contribute to the light emission. On the other hand, because electrons become less liable to move from the barrier layer to the well layer due to generation of the strain of energy band caused by the piezoelectric field, a sufficient amount of electrons cannot be accumulated in the well layer that is at the position closest to the p-type nitride semiconductor layer. Therefore, the light emission efficiency is improved by allowing at least the final barrier layer to contain n-type nitride to reduce the strain of energy band in order that a sufficient amount of electrons may be accumulated in the well layer that is at the position closest to the p-type nitride semiconductor layer that is considered to contribute most to the light emission.

The n-type impurity concentration into the barrier layer is preferably within a range from 5×10¹⁷/cm³ to 1×10¹⁹/cm³. When this n-type impurity concentration is smaller than 5×10¹⁷/cm³, the relaxation of piezoelectric field becomes less liable to occur, thereby raising a possibility of hindering the movement of electrons and lowering the light emission efficiency. On the other hand, when this n-type impurity concentration is larger than 1×10¹⁹/cm³, there is raised a possibility of generating a so-called overflow in which the electrons in the light-emitting layer are saturated and flow to the p-type nitride semiconductor layer side. In view of the relaxation of piezoelectric field, even the final barrier layer preferably contains the n-type impurities within the above range. However, adjustment of doping of the final barrier layer near the interface must be made so that the n-type impurity concentration at the interface with the p-type nitride semiconductor layer is 4×10¹⁷/cm³ or less. When the n-type impurity concentration is higher than 4×10¹⁷/cm³, the p-layer formed thereafter is of n-type, thereby raising a possibility of destroying the p-n junction and lowering the light emission efficiency.

In the above-described construction, all of the barrier layers including the final barrier layer may be made to contain n-type impurities. As will be described later with reference to the examples in the section of “MODE FOR CARRYING OUT THE INVENTION,” when a construction of not allowing some of the barrier layers to contain n-type impurities is compared with a construction of allowing all the barrier layers to contain n-type impurities under a condition such that the n-type impurity concentration at the interface between the final barrier layer and the p-type nitride semiconductor layer is commonly set to be 4×10¹⁷/cm³ or less, the latter has shown a higher light emission efficiency.

Also, a method for manufacturing the nitride semiconductor light-emitting element according to the present invention includes, at the time of forming the final barrier layer, the steps of:

supplying a mixed gas that contains a first source material gas for forming a material of the final barrier layer and a second source material gas for allowing the n-type impurities to be contained; and

stopping the supplying of the second source material gas while continuously supplying the first source material gas.

One example of the first source material gas may be a mixed gas of nitrogen, hydrogen, trimethylgallium, and trimethylindium. Also, as the second source material gas, silane can be adopted besides tetraethylsilane when, for example, Si is used as a dopant as n-type impurities.

According to the method of the present invention, the first source material gas and the second source material gas are supplied at an initial stage of forming the final barrier layer, and thereafter, the supply of the second source material gas is stopped while continuously supplying the first source material gas, thereby to form the final barrier layer. This allows that, while the n-type impurities made to contain at the initial stage are diffused to the surface side of the final barrier layer to set the n-type impurity concentration at the surface, that is, the n-type impurity concentration at the interface with the p-type nitride semiconductor layer formed thereafter, to be 4×10¹⁷/cm³ or less, the diffusion into the p-type nitride semiconductor layer can be suppressed to the minimum. According to this method, the n-type impurity concentration at the interface with the p-type nitride semiconductor layer can be adjusted to be a desirable value by controlling the period of time for supplying the second source material gas at the initial stage.

### Effect of the Invention

According to the present invention, a nitride semiconductor light-emitting element having excellent lifespan characteristics can be realized while improving light emission efficiency as compared with conventional elements.

### BRIEF DESCRIPTION OF THE DRAWINGS

FIG. 1 is a sectional view schematically illustrating a structure of a nitride semiconductor light-emitting element.

FIG. 2 is a sectional view schematically illustrating a part of the structure of the nitride semiconductor light-emitting element.

FIG. 3 is a graph schematically showing one example of a result of compositional analysis using SIMS on a nitride semiconductor light-emitting element.

FIG. 4 is a graph showing a relationship between the emission light quantity of each of the elements of Examples 1 to 5 and Comparative Examples 1 to 2 and the supply current.

FIG. 5 is a graph showing a result of evaluating withstand voltage characteristics when a reverse bias voltage is applied to each of the elements of Examples 1 to 5 and Comparative Examples 1 to 2.

### MODE FOR CARRYING OUT THE INVENTION

A nitride semiconductor light-emitting element and a method for manufacturing the same according to the present invention will be described with reference to the drawings. In each of the drawings, the dimension ratio in the drawings does not necessarily coincide with the actual dimension ratio.

### [Structure]

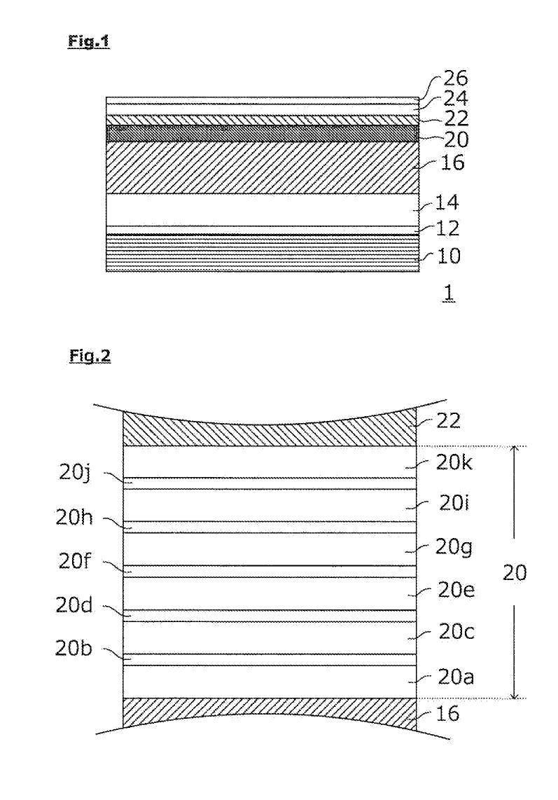

FIG. 1 is a sectional view schematically illustrating a structure of a nitride semiconductor light-emitting element. A nitride semiconductor light-emitting element 1 is constructed to include a light-emitting layer 20 formed between an n-type nitride semiconductor layer 16 and a p-type nitride semiconductor layer 22. More specifically, the nitride semiconductor light-emitting element 1 includes, on top of a support substrate 10 such as sapphire, a first buffer layer 12, a second buffer layer 14, the n-type nitride semiconductor layer 16, the light-emitting layer 20, the p-type nitride semiconductor layer 22, a p-type cladding layer 24, and a p-type contact layer 26 in this order from below.

Hereafter, a further detailed construction of the nitride semiconductor light-emitting element 1 will be described.

### (Support Substrate 10)

The support substrate 10 is constituted of a sapphire substrate. Instead of sapphire, the support substrate 10 may be constituted of Si, SiC, GaN, YAG, or the like.

### (First Buffer Layer 12, Second Buffer Layer 14)

The first buffer layer 12 is formed of a GaN layer that is grown at a low temperature on the c-plane of the support substrate 10 (sapphire substrate). Also, the second buffer layer 14 is a GaN layer serving as an underlayer that is grown at a high temperature on top of the first buffer layer 12. The two layers both constitute undoped layers.

### (N-Type Nitride Semiconductor Layer 16)

The n-type nitride semiconductor layer 16 is constituted of n-AlGa₁₋ₙN (0≦n<1) that is grown at a high temperature on top of the second buffer layer 14. As one example, the n-type nitride semiconductor layer 16 is formed of n-Al_{0.06}Ga_{0.94}N in the present embodiment. As the n-type impurities serving as a dopant, Si is suitably used; however, Ge, S, Se, Sn, Te, or the like can be used as well.

A construction may be adopted in which a region that is in contact with the second buffer layer 14 includes a layer constituted of n-GaN (protective layer). In this case, a construction is adopted in which at least the protective layer is doped with the n-type impurities described above.

### (P-Type Nitride Semiconductor Layer 22, P-Type Cladding Layer 24)

The p-type nitride semiconductor layer 22 is constituted of p-AlₘGa₁₋ₘN (0≦m<1) that is grown on top of the light-emitting layer 20. Further, the p-type cladding layer 24 is constituted of p-AlₐGa₁₋ₐN (0≦a<1) that is grown on top of the p-type nitride semiconductor layer 22. As one example, the p-type nitride semiconductor layer 22 is formed of p-Al_{0.3}Ga_{0.7}N, and the p-type cladding layer 24 is formed of p-Al_{0.13}Ga_{0.87}N in the present embodiment. As the n-type impurities serving as a dopant, Mg is suitably used; however, Be, Zn, C, or the like can be used as well.

### (P-Type Contact Layer 26)

The p-type contact layer 26 is constituted, for example, of p⁺-GaN or p⁺-AlGaN that is grown on top of the p-type cladding layer 24. For example, the p-type contact layer 26 is formed of GaN or AlGaN doped with Mg at a high concentration; however, the p-type contact layer 26 may also be formed by being doped with Be, Zn, C, or the like at a high concentration.

### (Light-Emitting Layer 20)

A construction of the light-emitting layer 20 will be described with reference to FIG. 2. FIG. 2 is an enlarged sectional view schematically illustrating the light-emitting layer 20 and the parts in the neighborhood thereof in the nitride semiconductor light-emitting element 1.

The light-emitting layer 20 is constructed by alternately stacking barrier layers (20a, 20c, 20e, 20g, 20i, 20k) formed of a nitride semiconductor and well layers (20b, 20d, 20f, 20h, 20j) formed of a nitride semiconductor. In the present embodiment, a construction is adopted in which the light-emitting layer 20 has six barrier layers and five well layers; however, the number of barrier layers and well layers is merely one example, so that the number of layers can be suitably set.

The barrier layers (20a, 20c, 20e, 20g, 20i, 20k) are formed, for example, of Al_{b}Ga_{1-b}N (0<b≦1), and the well layers (20b, 20d, 20f, 20h, 20j) are formed, for example, of In_{c}Ga_{1-c}N (0<c≦1). As one example, the light-emitting layer 20 in the present embodiment is constituted of barrier layers (20a, 20c, 20e, 20g, 20i, 20k) formed of Al_{0.98}Ga_{0.92}N having a thickness of 20 nm and well layers (20b, 20d, 20f, 20h, 20j) formed of In_{0.03}Ga_{0.97}N having a thickness of 5 nm.

Further, the nitride semiconductor light-emitting element 1 is constructed in such a manner that, among the barrier layers, at least the barrier layer 20k formed at a position in contact with the p-type nitride semiconductor layer 22, that is, the final barrier layer 20k, contains n-type impurities, and the concentration of the n-type impurities at the interface with the p-type nitride semiconductor layer 22 is set to be 4×10¹⁷/cm³ or less.

### [Evaluation]

With respect to the construction shown in FIG. 2, the characteristics of the element were evaluated by changing the concentration of n-type impurities contained in the light-emitting layer 10, particularly the barrier layers (20a, 20c, 20e, 20g, 20i, 20k).

### EXAMPLE 1

All the barrier layers were set to have a thickness of 20 nm, and these were allowed to contain n-type impurities. Further, the final barrier layer 20k was formed so that the n-type impurity concentration at the interface with the p-type nitride semiconductor layer 22 would be 3×10¹⁶/cm³.

In forming the final barrier layer 20k, tetraethylsilane (TESi), which is a source material gas for doping with Si constituting the n-type impurity, is mixed in addition to nitrogen, hydrogen, trimethylgallium (TMG), and trimethylaluminum (TMA) that constitute a source material gas of Al_{b}Ga_{1-b}N, and the final barrier layer 20k is grown for a predetermined period of time. Thereafter, only the supply of TESi is stopped, and the growth is continued. This allows that the Si with which the final barrier layer 20k is doped by supply of TESi, that is, the n-type impurity, is diffused to the surface side of the final barrier layer 20k. By controlling the period of time for supplying TESi, the n-type impurity concentration at the surface of the final barrier layer 20k, that is, at the interface between the final barrier layer 20k and the p-type nitride semiconductor layer 22 formed thereafter, can be controlled.

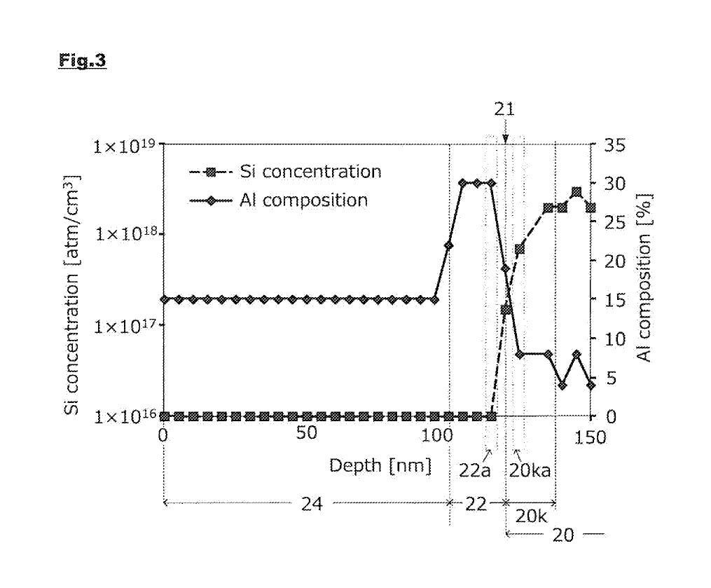

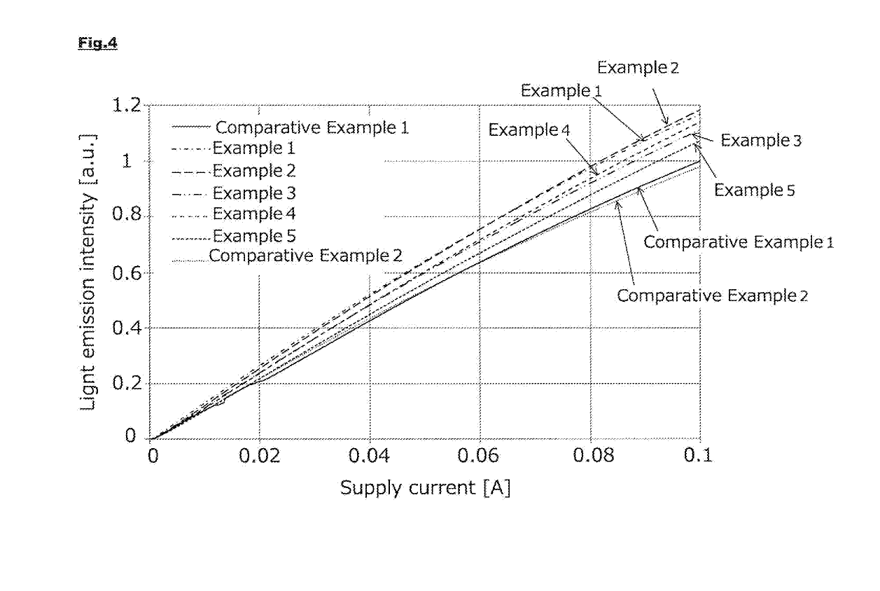

A method for measuring the n-type impurity concentration at the interface between the final barrier layer 20k and the p-type nitride semiconductor layer 22 will be described with reference to FIG. 3. FIG. 3 is a graph schematically showing one example of a result of compositional analysis using SIMS (Secondary Ion Mass Spectrometry) on the formed nitride semiconductor light-emitting element, where the horizontal axis represents the distance from the surface in the depth direction; the right vertical axis represents the Al composition ratio; and the left vertical axis represents the Si concentration. FIG. 3 shows a case in which analysis is made on an element in FIG. 1 that does not include the p-type contact layer 26.

In measuring the n-type impurity concentration using SIMS or the like, composition evaluation is carried out while etching the nitride semiconductor light-emitting element at a predetermined pitch in the depth direction from the surface of the element. In this case, the obtained values of the composition ratio assume discrete values that accord to the pitch of etching. FIG. 3 shows a graph schematically showing a result of compositional analysis at each measurement point by SIMS while etching the element at a 5 nm pitch in the depth direction from the surface.

When SIMS analysis is carried out while etching the nitride semiconductor light-emitting element in the depth direction from the uppermost surface, a signal deriving from the composition of the p-type cladding layer 24 constituted of p-Al_{0.13}Ga_{0.87}N is obtained for some time. This layer does not contain Si, which is an n-type impurity, while the layer contains Al, so that the value of the Al composition at a constant ratio and the value of an Si concentration of 1×10¹⁶/cm³, which is almost a detection limit of the n-type impurity concentration, are shown, as in FIG. 3.

When the etching is further carried out in the depth direction, a signal deriving from the p-type nitride semiconductor layer 22 (p-Al_{0.3}Ga_{0.7}N) formed below the p-type cladding layer 24 starts to be obtained. This layer has a higher Al composition ratio than the p-type cladding layer 24, so that the value of the Al composition rises. On the other hand, because this layer does not contain Si which is an n-type impurity, the value of an Si concentration of 1×10¹⁶/cm³, which is almost a detection limit of the n-type impurity concentration, is shown in the same manner as in the p-type cladding layer 24.

In FIG. 3, the etching is carried out at a 5 nm pitch so as to carry out a compositional analysis at each measurement point, so that the result of analysis obtained on the graph assumes discrete values. For this reason, the value of the composition ratio at positions between the measurement points cannot be obtained in the strict sense of the word. Therefore, as shown in FIG. 3, the discrete values obtained at the measurement points are linearly interpolated, so as to surmise the composition ratio at positions between the measurement points. When such a method is adopted, the finer the etching pitch is, the more preferable it is, because more precise values can be obtained. In the present embodiment, a 5 nm pitch is adopted; however, a pitch of 5 nm or less is preferable, and a pitch of 2 nm or less is more preferable.

When the etching is further carried out in the depth direction, a signal deriving from the final barrier layer 20k formed below the p-type nitride semiconductor layer 22 starts to be obtained. This final barrier layer 20k is constituted of Al_{0.08}Ga_{0.92}N containing an n-type impurity (Si), so that a signal of Al and a signal of Si are obtained from the measurement points in this layer. The numerical value of the Al composition ratio decreases because the final barrier layer 20k contains a smaller amount of Al than the p-type nitride semiconductor layer 22. On the other hand, the numerical value of the Si concentration increases because the final barrier layer 20k contains Si while the p-type nitride semiconductor layer 22 does not contain Si.

As described above, because the compositional analysis is carried out while etching the nitride semiconductor light-emitting element at a predetermined pitch, there is a possibility such that the interface between the p-type nitride semiconductor layer 22 and the final barrier layer 20k may not serve as a measurement point. More specifically, there is a possibility such that the measurement point 22a immediately before the relevant pitch may be a site that is in the p-type nitride semiconductor layer 22 and is the closest to the final barrier layer 20k, and the measurement point 20ka immediately after the relevant pitch may be a site that is in the final barrier layer 20k and is the closest to the p-type nitride semiconductor layer 22. In this case, it is not possible to measure the n-type impurity concentration at the interface between the final barrier layer 20k and the p-type nitride semiconductor layer 22 in the strict sense of the word.

Therefore, by using the linear interpolation described above, the interface between the final barrier layer 20k and the p-type nitride semiconductor layer 22 is defined to be a site where the Al composition difference between the final barrier layer 20k and the p-type nitride semiconductor layer 22 is ½. Referring to FIG. 3, according as the measurement is carried out at sites from the p-type nitride semiconductor layer 22 towards the final barrier layer 20k, the Al composition decreases, and the Si concentration increases. Therefore, by linearly interpolating the value of the Al composition at the measurement point 22a that is in the p-type nitride semiconductor layer 22 and is the closest to the final barrier layer 20k and the value of the Al composition at the measurement point 20ka that is in the final barrier layer 20k and is the closest to the p-type nitride semiconductor layer 22, the position of the interface 21 between the final barrier layer 20k and the p-type nitride semiconductor layer 22 is determined as a site at which the value thereof assumes an intermediate value.

Further, referring to FIG. 3, by linearly interpolating the value of the Si concentration at the measurement point 22a that is in the p-type nitride semiconductor layer 22 and is the closest to the final barrier layer 20k and the value of the Si concentration at the measurement point 20ka that is in the final barrier layer 20k and is the closest to the p-type nitride semiconductor layer 22, the value of the Si concentration at the position of the interface 21 is deduced.

In Example 1, in forming the final barrier layer 20k, TESi as well as nitrogen, hydrogen, TMG, and TMA are supplied for the initial period of about 120 seconds, so as to grow the final barrier layer 20k to 5 nm while allowing the final barrier layer 20k to contain the n-type impurity. Thereafter, by stopping the supply of TESi and supplying nitrogen, hydrogen, TMG, and TMA for about 360 seconds to grow the final barrier layer 20k, the final barrier layer 20k eventually having a thickness of 20 nm was formed in about 480 seconds. By this process, the n-type impurity concentration at the interface of the final barrier layer 20k to the p-type nitride semiconductor layer 22 was let to be 3×10¹⁶/cm³.

In the following examples and comparative examples also, the n-type impurity concentration at the interface between the final barrier layer 20k and the p-type nitride semiconductor layer 22 was measured by the method described above.

### EXAMPLE 2

An element was formed in the same manner as in Example 1 except that, in forming the final barrier layer 20k, the period of time for supplying TESi was set to be about 240 seconds to grow the final barrier layer 20k to 10 nm while allowing the final barrier layer 20k to contain the n-type impurity and that, by stopping the supply of TESi thereafter and supplying nitrogen, hydrogen, TMG, and TMA for about 240 seconds, the final barrier layer 20k eventually having a thickness of 20 nm was formed in about 480 seconds. This allowed that, in the element of Example 2, the n-type impurity concentration at the interface between the final barrier layer 20k and the p-type nitride semiconductor layer 22 was 7×10¹⁶/cm³.

### EXAMPLE 3

An element was formed under the same conditions as in Example 2 except that a part of the barrier layers (20a, 20c, 20e, 20g, 20i, 20k), that is, the barrier layer 20g, was left undoped.

### EXAMPLE 4

An element was formed in the same manner as in Example 1 except that, in forming the final barrier layer 20k, the period of time for supplying TESi was set to be about 288 seconds to grow the final barrier layer 20k to 12 nm while allowing the final barrier layer 20k to contain the n-type impurity and that, by stopping the supply of TESi thereafter and supplying nitrogen, hydrogen, TMG, and TMA for about 192 seconds, the final barrier layer 20k eventually having a thickness of 20 nm was formed in about 480 seconds. This allowed that, in the element of Example 4, the n-type impurity concentration at the interface between the final barrier layer 20k and the p-type nitride semiconductor layer 22 was 1.5×10¹⁷/cm³.

### EXAMPLE 5

An element was formed in the same manner as in Example 1 except that, in forming the final barrier layer 20k, the period of time for supplying TESi was set to be about 360 seconds to grow the final barrier layer 20k to 15 nm while allowing the final barrier layer 20k to contain the n-type impurity and that, by stopping the supply of TESi thereafter and supplying nitrogen, hydrogen, TMG, and TMA for about 120 seconds, the final barrier layer 20k eventually having a thickness of 20 nm was formed in about 480 seconds. This allowed that, in the element of Example 5, the n-type impurity concentration at the interface between the final barrier layer 20k and the p-type nitride semiconductor layer 22 was 4×10¹⁷/cm³.

### COMPARATIVE EXAMPLE 1

An element was formed in the same manner as in Example 1 except that the final barrier layer 20k was left undoped by forming the final barrier layer 20k without supplying TESi.

### COMPARATIVE EXAMPLE 2

An element was formed in the same manner as in Example 1 except that, in forming the final barrier layer 20k, the period of time for supplying TESi was set to be about 456 seconds to grow the final barrier layer 20k to 19 nm while allowing the final barrier layer 20k to contain the n-type impurity and that, by stopping the supply of TESi thereafter and supplying nitrogen, hydrogen, TMG, and TMA for about 24 seconds, the final barrier layer 20k eventually having a thickness of 20 nm was formed in about 480 seconds. This allowed that, in the element of Comparative Example 1, the n-type impurity concentration at the interface between the final barrier layer 20k and the p-type nitride semiconductor layer 22 was 8×10¹⁷/cm³.

FIG. 4 is a graph showing a relationship between the emission light quantity of each of the elements of Examples 1 to 5 and Comparative Examples 1 to 2 and the supply current. According to FIG. 4, it will be understood that Example 2 in which the n-type impurity concentration at the interface between the final barrier layer 20k and the p-type nitride semiconductor layer 22 (hereafter abbreviated as “interface concentration” as appropriate) is set to be 7×10¹⁶/cm³ gives the largest emission light quantity, and that the emission light quantity is large in the order from Example 1 in which the interface concentration is set to be 3×10¹⁶/cm³ to Example 4 in which the interface concentration is set to be 1.5×10¹⁷/cm³.

Also, it will be understood that Example 3 in which the interface concentration is set to be 7×10¹⁶/cm³ and a part of the barrier layers (barrier layer 20g) is left undoped gives a larger emission light quantity than Comparative Example 1 in which the final barrier layer 20k is left undoped, though Example 3 gives a smaller emission light quantity than Example 2 in which all the barrier layers are doped with n-type impurities while the interface concentration is kept under the same conditions.

Example 5 in which the interface concentration is set to be 4×10¹⁷/cm³ gives a larger emission light quantity than Comparative Example 1 in which the final barrier layer 20k is left undoped, though Example 5 gives a smaller emission light quantity than Examples 1 to 4. On the other hand, Comparative Example 2 in which the interface concentration is set to be 8×10¹⁷/cm³ gives a smaller emission light quantity than Comparative Example 1 in which the final barrier layer 20k is left undoped.

According to FIG. 4, it will be understood that, by doping the final barrier layer 20k with n-type impurities and setting the n-type impurity concentration at the interface between the final barrier layer 20k and the p-type nitride semiconductor layer 22 to be 4×10¹⁷/cm³ or less, the light emission efficiency is improved as compared with conventional elements in which the final barrier layer 20k is left undoped. Also, when Example 2 is compared with Example 3, it will be understood that the light emission efficiency is improved when all the barrier layers are doped with n-type impurities; however, by setting the n-type impurity concentration at the interface between the final barrier layer 20k and the p-type nitride semiconductor layer 22 to be 4×10¹⁷/cm³ or less, the light emission efficiency is improved even if a part of the barrier layers is left undoped, as compared with conventional elements in which the final barrier layer 20k is left undoped.

It seems that, when the interface concentration is set to be 8×10¹⁷/cm³ as in Comparative Example 2, a part of the n-type impurities is diffused from the final barrier layer 20k to the p-type nitride semiconductor layer 22, giving damages to the p-n junction to decrease the injection efficiency thereby to invite deterioration of the characteristics.

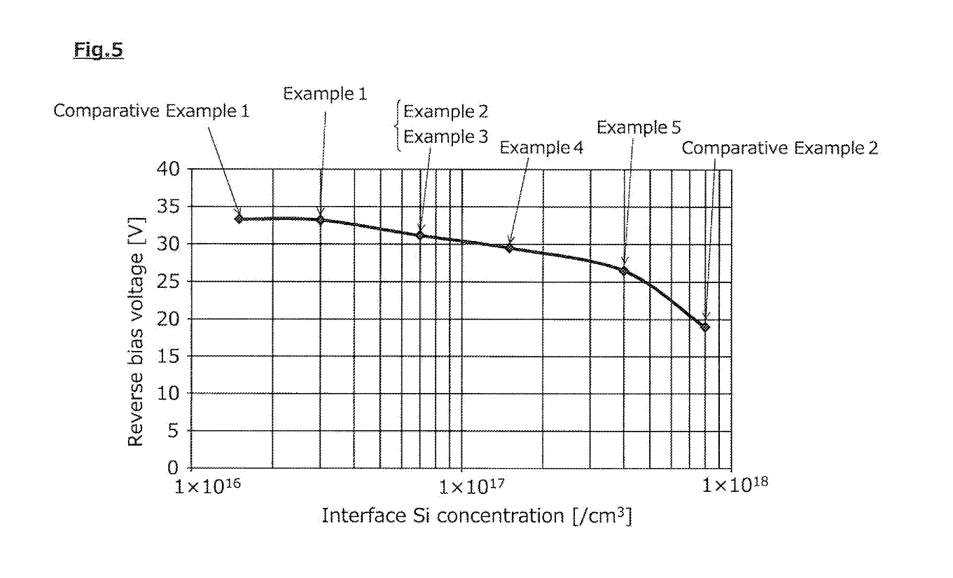

FIG. 5 is a graph showing a result of evaluating withstand voltage characteristics when a reverse bias voltage is applied to each of the elements of Examples 1 to 5 and Comparative Examples 1 to 2. The horizontal axis represents the interface concentration, and the vertical axis represents the magnitude of the reverse bias voltage needed for allowing the reverse bias current to flow at 1 μA. In Comparative Example 1, the interface concentration is 1.5×10¹⁶; however, this is a value derived from noises and is substantially a measurement limit, so that this may be regarded as being undoped in actual cases.

With reference to FIG. 5 also, it will be understood that, when the interface concentration is increased to be as high as 8×10¹⁷/cm³ as in Comparative Example 2, the withstand voltage is considerably low. This result, too, shows that a part of the n-type impurities is diffused from the final barrier layer 20k to the p-type nitride semiconductor layer 22, giving damages to the p-n junction to decrease the withstand voltage. On the other hand, in Examples 1 to 5 in which the interface concentration is set to be 4×10¹⁷/cm³ or less, a high withstand voltage is shown, suggesting that there is no generation of leakage current, and an element having a long lifespan has been realized.

### [Manufacturing Method]

Next, one example of a method for manufacturing the nitride semiconductor light-emitting element 1 will be described. The production conditions and the dimensions such as the film thickness in the following description of the manufacturing method are merely examples, so that the present invention is not limited to these numerical values. In other words, in the steps of growing each semiconductor layer, it can be assumed that the vapor phase growth is carried out under conditions that attain a substrate temperature and an in-furnace pressure that accord to the intended composition.

In the following, description will be given on a method for manufacturing the nitride semiconductor light-emitting element 1 by growing each semiconductor layer using the MOCVD (Metal Organic Chemical Vapor Deposition) method. When this method is used, trimethylaluminum (TMA) is used as an organic metal compound constituting an Al atom supply source; trimethylgallium (TMG) is used as an organic metal compound constituting a Ga atom supply source; trimethylindium (TMI) is used as an organic metal compound constituting an In atom supply source; tetraethylsilane (TESi) is used as an organic metal compound constituting an Si atom supply source; biscyclopentadienylmagnesium (Cp₂Mg) is used as an organic metal compound constituting an Mg atom supply source; and ammonia is used as a compound constituting an N atom supply source, and a nitrogen gas and a hydrogen gas are used as carrier gases; however, the present invention is not limited to these.

### <Step S1>

First, a c-plane sapphire substrate is prepared as a support substrate 10, and this is cleaned. More specifically, this cleaning is carried out, for example, by placing the c-plane sapphire substrate in a processing furnace of an MOCVD (Metal Organic Chemical Vapor Deposition) apparatus and raising the temperature within the furnace to be, for example, 1150° C. while allowing a hydrogen gas to flow at a flow rate of 10 slm in the processing furnace.

### <Step S2>

Next, in a state in which the pressure within the furnace is 100 kPa and the substrate temperature is 480° C., ammonia at a flow rate of 250000 μmol/min and TMG at a flow rate of 50 μmol/min are supplied for 70 seconds into the processing furnace while supplying a nitrogen gas at a flow rate of 5 slm and a hydrogen gas at a flow rate of 5 slm as carrier gases into the processing furnace, whereby a GaN layer having a thickness of 20 nm is grown on the surface of the support substrate 10 to form a first buffer layer (LT-GaN) 12.

### <Step S3>

Next, in a state in which the substrate temperature is 1150° C., ammonia at a flow rate of 250000 μmol/min and TMG at a flow rate of 100 μmol/min are supplied for 30 minutes into the processing furnace while supplying a nitrogen gas at a flow rate of 20 slm and a hydrogen gas at a flow rate of 15 slm as carrier gases into the processing furnace, whereby an undoped GaN layer having a thickness of 1.7 μm is grown on the first buffer layer 12 to form a second buffer layer (u-GaN) 14.

### <Step S4>

Next, an n-type nitride semiconductor layer 16 constituted of n-AlₙGa₁₋ₙN (0≦n<1) is formed on top of the second buffer layer 14. More specifically, in a state in which the substrate temperature is 1150° C. and the pressure within the furnace is 30 kPa, TMA at a flow rate of 5.2 μmol/min and TESi at a flow rate of 0.013 μmol/min are supplied into the processing furnace while supplying a nitrogen gas at a flow rate of 20 slm and a hydrogen gas at a flow rate of 15 slm as carrier gases into the processing furnace in the same manner as in the step S3, whereby an n-type nitride semiconductor layer 16 constituted of an n-Al_{0.06}Ga_{0.94}N layer having a thickness of 2.3 μm is formed on the second buffer layer 14.

In the present step, Si was used as the n-type impurity serving as a dopant; however, besides this, Ge, S, Se, Sn, Te, and the like can be used.

### <Step S5>

Next, a light-emitting layer 20 made by alternate repetition of well layers made of In_{c}Ga_{1-c}N (0<c≦1) and barrier layers made of Al_{b}Ga_{1-b}N (0<b≦1) is formed on top of the n-type nitride semiconductor layer 16.

A more specific method of forming the light-emitting layer 20 is, for example, as follows. After the step S4, the growth step is interrupted. Thereafter, while supplying a nitrogen gas at a flow rate of 15 slm and a hydrogen gas at a flow rate of 1 slm as carrier gases into the processing furnace, in a state in which the pressure within the furnace is 100 kPa and the substrate temperature is 820° C., a step of forming a well layer having a composition of In_{0.03}Ga_{0.97}N having a thickness of 5 nm by supplying TMG at a flow rate of 10 μmol/min and TMI at a flow rate of 7 μmol/min for 120 seconds into the processing furnace and a step of forming a barrier layer having a composition of n-Al_{0.08}Ga_{0.92}N having a thickness of 20 nm by supplying TMG at a flow rate of 10 μmol/min, TMA at a flow rate of 0.9 μmol/min, and TESi at a flow rate of 0.9 μmol/min for 480 seconds into the processing furnace are carried out. Thereafter, by repeating these two steps, the well layers and the barrier layers are stacked for 5 periods. Doping the barrier layer with Si may be carried out either by doping the whole barrier layer or by partially doping the barrier layer if there is a fear that the injection efficiency may decrease due to entry of Si in an excessive amount into the InGaN layer, which is the well layer, by diffusion of Si.

Further, after the final well layer 20j is formed, TMG at a flow rate of 10 μmol/min, TMA at a flow rate of 0.9 μmol/min, and TESi at a flow rate of 0.9 μmol/min are supplied for a predetermined period of time. Thereafter, the supply of TESi is stopped, and continuously, TMG at a flow rate of 10 μmol/min and TMA at a flow rate of 0.9 μmol/min are supplied to form the final barrier layer 20k having a composition of n-Al_{0.08}Ga_{0.92}N having a thickness of 20 nm. As described above, by adjusting the period of time for supplying TESi in this step, the concentration of n-type impurities on the surface of the final barrier layer 20k, that is, at the interface with a p-type nitride semiconductor layer 22 formed in the next step S6, can be set to be 4×10¹⁷/cm³ or less.

### <Step S6>

While supplying a nitrogen gas at a flow rate of 15 slm and a hydrogen gas at a flow rate of 25 slm as carrier gases into the processing furnace at an in-furnace pressure of 100 kPa, the substrate temperature is set to be 1025° C., and in that state, TMG at a flow rate of 100 μmol/min, TMA at a flow rate of 24 μmol/min, and Cp₂Mg at a flow rate of 0.1 μmol/min are supplied for 20 seconds to grow a p-Al_{0.3}Ga_{0.7}N layer having a thickness of 20 nm on the light-emitting layer 20, thereby to form the p-type nitride semiconductor layer 22.

### <Step S7>

Subsequently, the flow rate of TMA is changed to 12 μmol/min, and the growth is continued for 100 seconds, thereby to form a p-type cladding layer 24 made of p-Al_{0.13}Ga_{0.87}N having a thickness of 100 nm on the p-type nitride semiconductor layer 22.

### <Step S8>

After the step S7, the flow rate of Cp₂Mg is changed to 0.2 μmol/min, and the growth is continued for 20 seconds, thereby to form a p-type contact layer 26 made of p⁺-type Al_{0.1}Ga_{0.9}N having a thickness of 20 nm on the p-type cladding layer 24.

### <Step S9>

Next, an activation process is carried out on the wafer obtained by passing through the steps S1 to S8. More specifically, an activation process of 15 minutes at 700° C. in an ambient atmosphere is carried out using an RTA (Rapid Thermal Anneal) apparatus.

### <Step S10>

Thereafter, an n-pad part is formed by etching a part of the n-type nitride semiconductor layer for exposure using photolithography and an inductively coupled plasma processing apparatus (ICP). Then, an electrode material (for example, Ni to 5 nm and gold to 5 nm) is formed on each of the n-pad part and a p-pad part which is set on the surface of the p-type contact layer 26. Thereafter, annealing is carried out at a temperature of 500° C. in an ambient atmosphere for 5 minutes, and Al is vapor-deposited on each of the n-pad part and the p-pad part to form an n-electrode and a p-electrode.

Also, in the case of realizing an element of longitudinal type, the support substrate 10 is peeled off, and thereafter, an electrode material is stacked at a site where the support substrate 10 was present, thereby to form an n-electrode. Further, a p-electrode is formed on a p-pad part which is set on the surface of the p-type contact layer 26 by a method similar to the one described above.

### DESCRIPTION OF REFERENCE SIGNS

1: Nitride semiconductor light-emitting element
10: Support substrate
12: First buffer layer
14: Second buffer layer
16: n-type nitride semiconductor layer
20: Light-emitting layer
20a, 20c, 20e, 20g, 20i, 20k: Barrier layer
20b, 20d, 20f, 20h, 20j: Well layer
20ka: Measurement point that is in the final barrier layer 20k and is the closest to the p-type nitride semiconductor layer 22
21: Interface between the final barrier layer 20k and the p-type nitride semiconductor layer 22
22: p-type nitride semiconductor layer
22a: Measurement point that is in the p-type nitride semiconductor layer 22 and is the closest to the final barrier layer 20k
24: p-type cladding layer
26: p-type contact layer

1. A nitride semiconductor light-emitting element comprising:
an n-type nitride semiconductor layer;
a p-type nitride semiconductor layer; and
a light-emitting layer formed between the n-type nitride semiconductor layer and the p-type nitride semiconductor layer,
the light-emitting layer being obtained by alternately stacking at least one well layer comprising a nitride semiconductor and at least one barrier layer comprising a nitride semiconductor,
wherein a final barrier layer among the barrier layer(s), which is a barrier layer formed at a position in contact with the p-type nitride semiconductor layer, contains n-type impurities, and the concentration of the n-type impurities at an interface with the p-type nitride semiconductor layer is 4×10¹⁷/cm³ or less.

2. The nitride semiconductor light-emitting element according to claim 1, wherein all of the barrier layer(s) including the final barrier layer contain n-type impurities.

3. A method for manufacturing the nitride semiconductor light-emitting element according to claim 1, comprising, at the time of forming the final barrier layer, the steps of:
supplying a mixed gas that contains a first source material gas for forming a material of the final barrier layer and a second source material gas for allowing the n-type impurities to be contained; and
stopping the supplying of the second source material gas while continuously supplying the first source material gas.
